(19) United States
(12) Patent Application Publication
(10) Pub. No.: US 2023/0332015 A1
(43) Pub. Date: Oct. 19, 2023

(54) SLURRY COMPOSITION FOR POLISHING METAL AND METHOD OF MANUFACTURING INTEGRATED CIRCUIT DEVICE USING THE SAME

(71) Applicant: SAMSUNG ELECTRONICS CO., LTD., Suwon-si (KR)

(72) Inventors: Inkwon KIM, Suwon-si (KR); Yearin Byun, Suwon-si (KR); Sangkyun KIM, Suwon-si (KR); Boun YOON, Suwon-si (KR); Hyosan LEE, Suwon-si (KR)

(21) Appl. No.: 18/096,231

(22) Filed: Jan. 12, 2023

(30) Foreign Application Priority Data
Apr. 15, 2022 (KR) 10-2022-0047185

(51) Int. Cl. H01L 21/768; C09G 1/02; C09G 1/04; H01L 21/321

(52) U.S. Cl. CPC C09G 1/02; C09G 1/04; H01L 21/3212; H01L 21/7684; H01L 21/76843

(57) ABSTRACT

A slurry composition for polishing metal and a method of manufacturing an integrated circuit device, the slurry composition includes a first organic polishing booster including a cationic polymer salt that includes a quaternary ammonium cation; a second organic polishing booster including an organic acid; an oxidizer; a pH adjuster; 0 wt% to about 0.1 wt% of an inorganic abrasive; and water.

### CROSS-REFERENCE TO RELATED APPLICATION

This application is based on and claims priority under 35 U.S.C. §119 to Korean Patent Application No. 10-2022-0047185, filed on Apr. 15, 2022, in the Korean Intellectual Property Office, the disclosure of which is incorporated by reference herein in its entirety.

### BACKGROUND

### 1. Field

Embodiments relate to a slurry composition for polishing metal (hereinafter referred to as a metal-polishing slurry composition) and a method of manufacturing an IC device using the same.

### 2. Description of the Related Art

Due to the development of electronic technology, the downscaling of semiconductor devices has rapidly progressed. Accordingly, the linewidth and pitch of metal wiring layers included in IC devices have also been miniaturized. The lifespan and reliability of IC devices may be impro4ved by minimizing physical damage to wiring structures including metal wiring layers.

### SUMMARY

The embodiments may be realized by providing a slurry composition for polishing metal, the slurry composition including a first organic polishing booster including a cationic polymer salt that includes a quaternary ammonium cation; a second organic polishing booster including an organic acid; an oxidizer; a pH adjuster; 0 wt% to about 0.1 wt% of an inorganic abrasive; and water.

The embodiments may be realized by providing a slurry composition for processing a surface of a metal-containing film-containing object to be polished by a chemical mechanical polishing (CMP) process, the slurry composition including a first organic polishing booster including a cationic polymer salt that includes a quaternary ammonium cation; a second organic polishing booster including an organic acid; an oxidizer; a pH adjuster; and water.

The embodiments may be realized by providing a slurry composition for polishing metal, the slurry composition being formulated to process a surface of an object to be polished by a chemical mechanical polishing (CMP) process such that the object includes a copper (Cu) film, the slurry composition including a first organic polishing booster including a cationic polymer salt including a quaternary ammonium cation; a second organic polishing booster including an organic acid; an oxidizer; a pH adjuster; and water, wherein the slurry composition is free of an inorganic abrasive.

The embodiments may be realized by providing a method of manufacturing an integrated circuit device, the method including forming an object to be polished on a substrate such that the object includes a metal-containing film; and polishing the metal-containing film by a chemical mechanical polishing (CMP) process using a first slurry composition for polishing metal, wherein the first slurry composition includes a first organic polishing booster including a cationic polymer salt that includes a quaternary ammonium cation; a second organic polishing booster including an organic acid; an oxidizer; a pH adjuster; and water.

The embodiments may be realized by providing a method of manufacturing an integrated circuit device, the method including forming a copper (Cu) film on a substrate; and forming a planarized Cu film by polishing the Cu film by performing a chemical mechanical polishing (CMP) process using a slurry composition for polishing metal, wherein the slurry composition includes a first organic polishing booster including cationic polymer salt that includes a quaternary ammonium cation; a second organic polishing booster including an organic acid; an oxidizer; a pH adjuster; and water, wherein the slurry composition is free of an inorganic abrasive.

The embodiments may be realized by providing a method of manufacturing an integrated circuit device, the method including forming, on a substrate, an interlayer insulating film that includes a hole; forming a metal-containing film including a copper (Cu) film such that the metal-containing film fills an inside of the hole and covers the interlayer insulating film outside the hole; polishing a first portion of the Cu film using a first slurry composition for polishing metal, the first slurry composition being free of an inorganic abrasive; and simultaneously polishing a second portion of the Cu film and a portion of the interlayer insulating film using a second slurry composition for polishing metal, the second slurry composition including an inorganic abrasive, wherein each of the first slurry composition and the second slurry composition includes a first organic polishing booster including cationic polymer salt that includes a quaternary ammonium cation; a second organic polishing booster including an organic acid; an oxidizer; a pH adjuster; and water.

### BRIEF DESCRIPTION OF THE DRAWINGS

Features will be apparent to those of skill in the art by describing in detail exemplary embodiments with reference to the attached drawings in which:

FIG. 1 is a partially cut-away perspective view of some components of a polishing apparatus according to embodiments;

FIG. 2 is a flowchart of a method of manufacturing an integrated circuit (IC) device, according to embodiments;

FIGS. 3A and 3B are cross-sectional views of a stages in a method of manufacturing an IC device, according to embodiments;

FIG. 4 is a flowchart of a method of manufacturing an IC device, according to embodiments; and

FIGS. 5A to 5D are cross-sectional views of stages in a method of manufacturing an IC device, according to embodiments.

### DETAILED DESCRIPTION

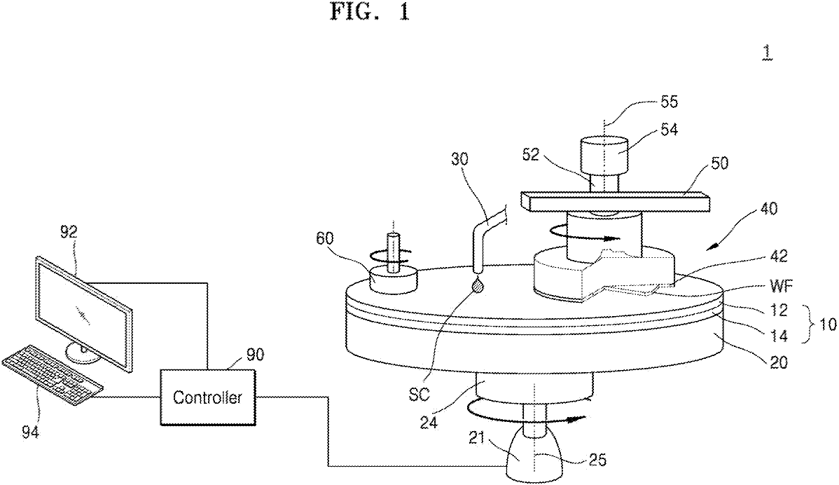

FIG. 1 is a partially cut-away perspective view of some components of a polishing apparatus 1 according to embodiments.

Referring to FIG. 1, the polishing apparatus 1 may be used to polish a surface of a wafer WF by using a chemical mechanical polishing (CMP) process. A rotary polishing apparatus is illustrated as an example of the polishing apparatus 1 in FIG. 1.

The polishing apparatus 1 may include a platen 20 having a rotating disc shape. The platen 20 may be capable of rotating about a central axis 25 thereof by using a motor 21. For example, the motor 21 may turn a driving axis 24 to rotate the platen 20. A polishing pad 10 is placed on a top surface of the platen 20. The polishing pad 10 may include a polishing layer 12 and a support layer 14. The support layer 14 may support the polishing pad 10 to be adhered to the platen 20.

A film to be polished, e.g., a metal-containing film and an insulating film, may be formed on the wafer WF. The wafer WF may include a structure configured to form an integrated circuit (IC) device, a structure configured to form a thin film transistor-liquid crystal display (TFT-LCD), glass substrate, or a structure including various structures, such as a ceramic substrate and a polymer substrate. As used herein, the term “or” is not an exclusive term, e.g., “A or B” would include A, B, or A and B.

The polishing apparatus 1 may include a slurry port 30 configured to dispense a metal-polishing slurry composition SC according to embodiments onto the polishing pad 10. The polishing apparatus 1 may include a polishing pad conditioner 60. The polishing pad conditioner 60 may perform a dressing operation of periodically polishing and planarizing a surface of the polishing pad 10 so that the polishing pad 10 may provide constant polishing efficiency.

The polishing apparatus 1 may include at least one carrier head 40. The wafer WF may be loaded on the carrier head 40. In a state in which the wafer WF loaded on the carrier head 40 is positioned to face the platen 20, the carrier head 40 may rotate while rotating the wafer WF toward the platen 20. In an implementation, as illustrated in FIG. 1, only one carrier head 40 may be on the polishing pad 10, or a plurality of carrier heads 40 may be on the polishing pad 10. The carrier head 40 may control pressure applied to the wafer WF.

The carrier head 40 may include a retaining ring 42 to hold the wafer WF. The carrier head 40 may be supported by a support structure 50 (e.g., a carousel or a track) and be connected to a carrier head rotational motor 54 by a driving axis 52, and thus, the carrier head 40 may rotate about a central axis 55 of the driving axis 52.

The polishing apparatus 1 may further include a control system configured to control rotation of the platen 20. The control system may include a controller 90 (e.g., a general-use programmable digital computer), an output device 92 (e.g., a monitor), and an input device 94 (e.g., a keyboard). In an implementation, as illustrated in FIG. 1, the control system may be connected only to the motor 21. The control system may also be connected to the carrier head 40 and control a pressure or rotation speed of the carrier head 40. Furthermore, the control system may be connected to the slurry port 30 and control the supplying of the metal-polishing slurry composition SC.

The metal-polishing slurry composition SC according to the embodiments may be used to polish a metal-containing film on the wafer WF. The metal-polishing slurry composition SC may include, e.g., as main components, a first organic polishing booster including cationic polymer salt including a quaternary ammonium cation, a second organic polishing booster including an organic acid, an oxidizer, a pH adjuster, about 0 wt% to about 0.1 wt% (e.g., based on a total weight of the composition) of an inorganic abrasive, and water.

In an implementation, the metal-polishing slurry composition SC may be an abrasive-free slurry composition including no inorganic abrasive, e.g., free of an inorganic abrasive or essentially free of an inorganic abrasive. As used herein, when an inorganic abrasive is referred to as being not included in the metal-polishing slurry composition, e.g., that the composition is free of an inorganic abrasive, it indicates that the inorganic abrasive has not been intentionally added to the metal-polishing slurry composition.

When a metal-containing film is polished by using some other slurry compositions including an inorganic abrasive, the inorganic abrasive could damage a polished surface of the metal-containing film, depending on polishing conditions. When the metal-containing film is polished by a slurry composition including an inorganic abrasive, the inorganic abrasive could damage or contaminate surfaces of meal-containing wirings and metal-containing patterns, which are obtained by polishing the metal-containing film. In addition, the inorganic abrasive could reduce the lifespan of a polishing pad (e.g., the polishing pad 10 shown in FIG. 1), which is used during a polishing process, thereby increasing polishing costs.

The metal-polishing slurry composition SC according to the embodiments may include the first organic polishing booster and the second organic polishing booster, and the metal-polishing slurry composition SC may polish the metal-containing film, which is a film to be polished, at an excellent polishing rate without including the inorganic abrasive, and a polishing selectivity of the metal-containing film with respect to an insulating film (e.g., a silicon oxide film) adjacent thereto may be improved.

The metal-polishing slurry composition SC according to the embodiments may be an abrasive-free slurry composition free of or including no inorganic abrasive, and damage and contamination may be prevented from occurring in the metal-containing film that is polished by using the metal-polishing slurry composition SC. In an implementation, during the polishing process using the metal-polishing slurry composition SC, abrasion of the polishing pad may be reduced, and thus, manufacturing costs of the IC device may be reduced.

In an implementation, the metal-polishing slurry composition SC according to the embodiments may be used to polish a metal-containing film, e.g., a metal-containing film including a copper (Cu) film, a Cu alloy film, a molybdenum (Mo) film, a Mo alloy film, a tungsten (W) film, a W alloy film, a cobalt (Co) film, a Co alloy film, a ruthenium (Ru) film, a Ru alloy film, or a combination thereof.

In an implementation, the metal-polishing slurry composition SC may be used to polish a metal-containing film, e.g., a Cu-containing film including a Cu film, a Cu alloy film, or a combination thereof. In an implementation, the metal-polishing slurry composition SC may be used to simultaneously polish the Cu-containing film and a conductive barrier film adjacent thereto, e.g., a conductive barrier film including a titanium (Ti) film, a tantalum (Ta) film, a titanium nitride (TiN) film, a tantalum nitride (TaN) film, or a combination thereof. In an implementation, the metal-polishing slurry composition SC may be used to simultaneously polish the Cu-containing film and an insulating film (e.g., a silicon oxide film) adjacent thereto.

In the metal-polishing slurry composition SC according to the embodiments, the first organic polishing booster may help increase a polishing rate of the metal-containing film.

In an implementation, the first organic polishing booster may have a molecular weight of about 1,000 to about 1,000,000. The molecular weight may be a weight-averaged molecular weight. The weight-averaged molecular weight may be measured by gel permeation chromatography (GPC) using polystyrene as a standard. If the first organic polishing booster were to have an excessively low molecular weight, the polishing rate could be reduced. If the first organic polishing booster were to have an excessively high molecular weight, dispersibility could be lowered and thus, uniform polishing could be difficult.

In an implementation, the first organic polishing booster may include a polymer including a structural unit represented by, e.g., one of Formulae 1 to 6. In Formulae 1 to 6, “*” denotes a binding site.

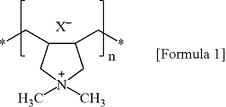

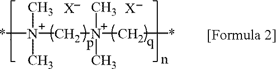

In Formula 1, X may be, e.g., fluorine (F), chlorine (Cl), bromine (Br), or iodine (I). n may be, e.g., an integer such that a molecular weight of the polymer including the structural unit represented by Formula 1 is about 1,000 to 1,000,000.

In Formula 2, each X may be, e.g., F, Cl, Br, or I. p and q may each independently be, e.g., an integer of 1 to 5. n may be, e.g., an integer such that a molecular weight of the polymer including the structural unit represented by Formula 2 is about 1,000 to 1,000,000.

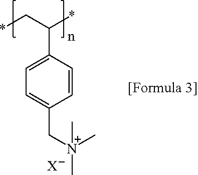

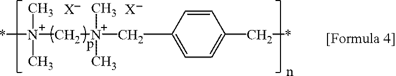

In Formula 3, X may be, e.g., F, Cl, Br, or I. n may be, e.g., an integer such that a molecular weight of the polymer including the structural unit represented by Formula 3 is about 1,000 to 1,000,000.

In Formula 4, each X may be, e.g., F, Cl, Br, or I. p may be, e.g., an integer of 1 to 5. n may be, e.g., an integer such that a molecular weight of the polymer including the structural unit represented by Formula 4 is about 1,000 to 1,000,000.

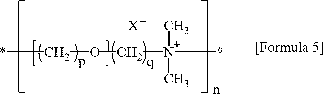

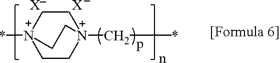

In Formula 5, X may be, e.g., F, Cl, Br, or I. p and q may each independently be, e.g., an integer of 1 to 5. n may be, e.g., an integer such that a molecular weight of the polymer including the structural unit represented by Formula 5 is about 1,000 to 1,000,000.

In Formula 6, each X may be, e.g., F, Cl, Br, or I. p may be, e.g., an integer of 1 to 5. n may be, e.g., an integer such that a molecular weight of the polymer including the structural unit represented by Formula 6 is about 1,000 to 1,000,000.

In an implementation, in the metal-polishing slurry composition SC, the first organic polishing booster may include a polymer including a structural unit represented by one of, e.g., Formulae 1 to 3. In an implementation, in the polymer including a structural unit represented by Formula 1, X may be Cl. In an implementation, in the polymer including a structural unit represented by Formula 2, X may be Br, p may be 5, and q may be 3. In an implementation, in the polymer including a structural unit represented by Formula 3, X may be Cl.

In the metal-polishing slurry composition SC, the first organic polishing booster may be included in an amount of, e.g., about 0.001 wt% to about 10 wt%, based on a total weight of the composition. If the amount of the first organic polishing booster were to be excessively low, an effect of improving a polishing rate by the first organic polishing booster could be unsatisfactory. If the content of the first organic polishing booster were to be excessively high, a polishing rate could be difficult to control, and surface defects could occur on a surface to be polished.

In the metal-polishing slurry composition SC according to the embodiments, the second organic polishing booster may not only help increase a polishing rate of the metal-containing film, but may also serve as a chelator.

In an implementation, the second organic polishing booster may include, e.g., arginine, histidine, lysine, aspartic acid, glutamic acid, serine, threonine, asparagine, glutamine, cysteine, selenocysteine, glycine, proline, alanine, valine, leucine, isoleucine, methionine, phenylalanine, tyrosine, tryptophan, carboxylic acid, or a combination thereof. As the second organic polishing booster, one type of material may be used alone or at least two types of materials may be mixed and used.

In an implementation, the second organic polishing booster may be included in an amount of, e.g., about 0.001 wt% to about 10 wt%, based on a total weight of the composition. If the amount of the second organic polishing booster were to be excessively low, an effect of improving a polishing rate by the second organic polishing booster could be unsatisfactory. If the content of the second organic polishing booster were to be excessively high, a polishing rate could be difficult to control, and surface defects could occur on the surface to be polished.

The metal-polishing slurry composition SC according to the embodiments may include both the first organic polishing booster and the second organic polishing booster, and even when the metal-polishing slurry composition SC does not include the inorganic abrasive, a polishing rate of the metal-containing film may be greatly increased, compared to other slurry compositions including an inorganic abrasive. In addition, when a surface at which the metal-containing film and the silicon oxide film are simultaneously exposed is polished by using the metal-polishing slurry composition SC, an etch selectivity of the metal-containing film with respect to the silicon oxide film may be markedly increased. In an implementation, to facilitate the control of the polishing rate of the metal-containing film, an amount of the first organic polishing booster may be lower than an amount of the second organic polishing booster in the metal-polishing slurry composition SC.

In the metal-polishing slurry composition SC according to the embodiments, the oxidizer may include a material capable of oxidizing a metal included in the metal-containing film, which is the film to be polished. The oxidizer may help improve the polishing rate of the metal-containing film by oxidizing the metal included in the metal-containing film.

In an implementation, the oxidizer may include, e.g., a peroxide, a permanganate, a periodate, an iodate, a nitrate, hypochlorous acid, a hypochlorite, a persulfate, or a combination thereof. In an implementation, the oxidizer may include, e.g., hydrogen peroxide, potassium permanganate, sodium periodate, potassium iodate, potassium nitrate, hypochlorous acid, sodium hypochlorite, potassium hypochlorite, ammonium persulfate, or a combination thereof. As the oxidizer, one type of material may be used alone or at least two types of materials may be mixed and used.

In an implementation, the oxidizer may be included in an amount of about 0.001% to about 10% by volume, e.g., about 0.001% to about 5% by volume, about 0.001% to about 3% by volume, or about 0.001% to about 1% by volume, based on a total volume of the metal-polishing slurry composition CS. If an amount of the oxidizer were to be excessively low in the metal-polishing slurry composition CS, a polishing rate could be excessively low because the oxidation of the metal-containing film, as the film to be polished, could be insufficient. If the amount of the oxidizer were to be excessively high, the metal-containing film could be excessively oxidized, and thus, a recess could be formed in the surface to be polished or the roughness of the surface to be polished could be degraded. As a result, it could be difficult to obtain a resultant structure having a desired shape.

In the metal-polishing slurry composition SC according to the embodiments, the pH adjuster may adjust the metal-polishing slurry composition SC to a pH value of about 2 to about 11.

In an implementation, the pH adjuster may include, e.g., potassium hydroxide, acetic acid, nitric acid, hydrogen chloride, ammonium hydroxide, sodium hydroxide, tetramethylammonium hydroxide, or a combination thereof.

In an implementation, the metal-polishing slurry composition SC may have a pH of, e.g., about 2 to about 11. In an implementation, the metal-polishing slurry composition SC may have, e.g., a pH value of about 4 to about 10 or a pH value of about 5 to about 8. To adjust a pH value of the metal-polishing slurry composition SC to a desired value, a pH adjuster including an acidic solution or an alkali solution may be used in an appropriate amount. In the metal-polishing slurry composition SC, the pH adjuster may be included in an amount suitable to adjust the metal-polishing slurry composition SC to a desired pH value.

Water included in the metal-polishing slurry composition CS may be deionized water. An amount of water included in the metal-polishing slurry composition CS may be a suitable amount, e.g., at a content of the remaining percentage together with main components including the first organic polishing booster, the second organic polishing booster, the oxidizer, and the pH adjuster in the main-polishing slurry composition CS.

The metal-polishing slurry composition SC according to the embodiments may further include a corrosion inhibitor including a water-soluble polymer containing an azole-containing compound or an anionic carboxylic acid. The corrosion inhibitor may be selectively adhered to a surface of a surface of the metal included in the metal-containing film, which is the film to be polished, and may help effectively inhibit excessive corrosion of the metal-containing film while maintaining a good polishing rate of the metal-containing film.

In an implementation, the corrosion inhibitor may include an azole-containing compound, which may include, e.g., triazole, tetrazole, benzotriazole, tolytriazole, aminotriazole, aminobenzimidazole, pyrazole, imidazole, aminotetrazole, or a combination thereof. In an implementation, the corrosion inhibitor may include, e.g., 5-methyl-1H-benzotriazol, 2,2′-[[(5-methyl-1H-benzotriazole-1-yl)-methyl]imino]bis-ethanol, 1,2,4-triazole, 1,2,3-triazole, 1,2,3-triazolo[4,5-b]pyridine, or a combination thereof. As the corrosion inhibitor, one type of material selected from the materials described above may be used alone or at least two types of the materials may be mixed and used.

In an implementation, the corrosion inhibitor may be included in an amount of about 0.001 wt% to about 1 wt%, e.g., about 0.001 wt% to about 0.5 wt%, based on the total weight of the metal-polishing slurry composition CS. In the metal-polishing slurry composition CS, if the content of the corrosion inhibitor were to be excessively low or high, it could be difficult to maintain a good polishing rate of the metal-containing film, which is the film to be polished.

The metal-polishing slurry composition SC according to the embodiments may further include a catalyst including, e.g., an iron-containing compound.

The catalyst may help improve the oxidation ability of the metal-polishing slurry composition SC and increase a removal rate of the metal-containing film, which is the film to be polished.

In an implementation, the catalyst may include, e.g., ferric nitrate, iron sulfate, iron halides, iron-containing organic compounds, or a combination thereof. The iron halide may include, e.g., iron fluorides, iron chlorides, iron bromides, iron iodides, iron perchlorate, iron perbromates, iron periodates, or a combination thereof. In an implementation, the iron-containing organic compound may include, e.g., iron acetates, iron acetylacetonates, iron citrates, iron gluconates, iron malonates, iron oxalates, iron phthalates, iron succinates, or a combination thereof. As the catalyst, one type of material selected from the materials described above may be used alone or at least two types of the materials may be mixed and used.

In an implementation, the catalyst may be included in an amount of about 0.001 wt% to about 0.1 wt%, e.g., about 0.001 wt% to about 0.01 wt%, based on the total weight of the metal-polishing slurry composition SC.

The metal-polishing slurry composition SC according to the embodiments may further include a biocide. The biocide may help prevent the metal-polishing slurry composition SC or an object to be polished to which the metal-polishing slurry composition SC is applied, from being contaminated with microorganisms.

In an implementation, the biocide may include, e.g., an organo tin compound, salicylanilide, formaldehyde, a quaternary ammonium compound, 2-bromo-2-nitropropane-1,3-diol (bronopol), 2,2-dibromo-3-nitrilopropionamide (DBNPA), isothiazolone, carbamate, quaternary phosphonium salt (e.g., tetrakis(hydroxymethyl)-phosphonium sulfate (THPS)), sodium chloride, sodium hypochlorite, trichloroisocyanuric acid, dichloroisocyanuric acid, calcium hypochlorite, lithium hypochlorite, chlorine dioxide, ozone, hydrogen peroxide, or a combination thereof.

When the biocide is included in the metal-polishing slurry composition, the biocide may be included in an amount of, e.g., about 0.001 wt% to about 10 wt%, based on the total weight of the metal-polishing slurry composition. In an implementation, the biocide may be included in an amount of about 0.001 wt% to about 5 wt%, about 0.001 wt% to about 3 wt%, or about 0.001 wt% to about 1 wt%.

In an implementation, only the metal-containing film may be polished by using the metal-polishing slurry composition SC according to the embodiments. In an implementation, only a Cu film may be polished by using the metal-polishing slurry composition SC. In this case, the metal-polishing slurry composition SC may include an abrasive-free slurry composition, which does not include an inorganic abrasive, or may include only a very small amount of inorganic abrasive. In an implementation, when only the metal-containing film (e.g., the Cu film) is to be polished by using the metal-polishing slurry composition SC, an inorganic abrasive may be included in a very small amount of more than about 0 wt% and equal to or less than about 0.1 wt%, based on the total weight of the metal-polishing slurry composition SC, in the metal-polishing slurry composition SC. Therefore, in the process of polishing the metal-containing film using the metal-polishing slurry composition SC, damage to and contamination of the film to be polished due to the inorganic abrasive may be minimized, and the abrasion of the polishing pad used in the polishing process may be minimized.

In an implementation, a metal-containing film (e.g., a Cu film) and an insulating film (e.g., a silicon oxide film) may be simultaneously polished by using the metal-polishing slurry composition SC according to the embodiments. In this case, in the metal-polishing slurry composition SC, the inorganic abrasive may be included in an amount of about 0.1 wt% to about 20.0 wt%, based on the total weight of the metal-polishing slurry composition SC.

In an implementation, the inorganic abrasive may include, e.g., silica, alumina, ceria, titania, zirconia, magnesia, germania, mangania, or a combination thereof. In an implementation, the inorganic abrasive may have a size (e.g., D50 average diameter) of, e.g., about 10 nm to about 200 nm. In an implementation, the inorganic abrasive may have a size of, e.g., about 30 nm to about 150 nm or about 30 nm to about 100 nm.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Evaluation Example (Evaluation of Polishing Rate)

Each of a Cu film and a silicon oxide film included in a film to be polished was polished by using a metal-polishing slurry composition according to embodiments, and a polishing rate of each of the Cu film and the silicon oxide film was evaluated.

For the present evaluation, a metal-polishing slurry composition (Example 1) and a comparative metal-polishing slurry composition (Example 2) were prepared as follows.

As the metal-polishing slurry composition of Example 1, a metal-polishing slurry composition including about 0.01 wt% of a first organic polishing booster, about 1.0 wt% of a second organic polishing booster, about 1 % by volume of an oxidizer, and a remaining percentage of water was prepared based on a total weight of the metal-polishing slurry composition of Example 1. The metal-polishing slurry composition of Example 1 did not include an inorganic abrasive. A pH value of the metal-polishing slurry composition was adjusted to 7 by using potassium hydroxide (KOH).

In the metal-polishing slurry composition of Example 1, a polymer including a structural unit represented by Formula 1, in which X was Cl and a weight-averaged molecular weight was 55,000, was used as the first organic polishing booster, and glycine was used as the second organic polishing booster.

The metal-polishing slurry composition of Example 2 was prepared in the same way as the metal-polishing slurry composition of Example 1 except that the metal-polishing slurry composition of Example 2 further included about 3 wt% of an inorganic abrasive (silica with a diameter of about 80 nm to about 100 nm), based on a total weight of the metal-polishing slurry composition of Example 2 and the first organic polishing booster was omitted.

The Cu film and the silicon oxide film were polished by using the metal-polishing slurry composition of Example 1 and the metal-polishing slurry composition of Example 2. As polishing conditions, a polishing pressure was about 3 psi, a rotation rate of a platen was about 93 rpm, a rotation rate of a carrier head was about 87 rpm, and a flow rate of each of the metal-polishing slurry compositions was about 250 ml/min. Each of the Cu film and the silicon oxide film was polished by using the metal-polishing slurry composition of Example 1 and the metal-polishing slurry composition of Example 2. Thicknesses of each of the Cu film and the silicon oxide film before and after the polishing process were measured, and polishing rates (removal rates) were calculated as shown in Table 1.

TABLE 1

Polishing rate (Å/min)

| | Cu film | Silicon oxide film |
|---|---|---|
| Example 1 | 7,700 | 5 |
| Example 2 | 5,400 | 3 |

From the results of Table 1, it may be seen that the metal-polishing slurry composition of Example 1 had a significantly higher polishing rate of the Cu film as compared to the metal-polishing slurry composition of Example 2. In addition, it may be seen that the metal-polishing slurry composition of Example 1 had an excellent polishing selectivity of the Cu film with respect to the silicon oxide film.

The metal-polishing slurry composition of Example 1 included the first organic polishing booster and the second organic polishing booster and did not include the inorganic abrasive, and due to a synergistic effect of a combination of the first organic polishing booster and the second organic polishing booster, a polishing rate of the Cu film was improved, and the occurrence of defects (e.g., scratches) due to the inorganic abrasive may be greatly reduced on a polished surface of the Cu film.

Next, a method of manufacturing an IC device, according to embodiments, will be described in detail.

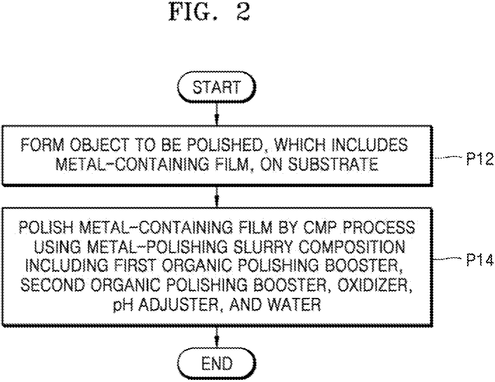

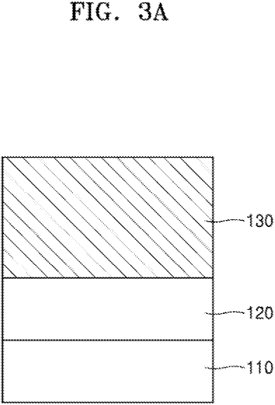

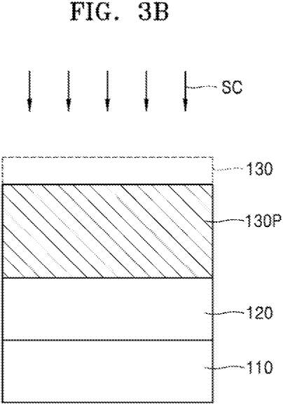

FIG. 2 is a flowchart of a method of manufacturing an IC device, according to embodiments. FIGS. 3A and 3B are cross-sectional views of stages in a method of manufacturing an IC device, according to embodiments.

Referring to FIGS. 2 and 3A, in process P12, a lower structure 120 may be formed on a substrate 110, and an object to be polished, which includes a metal-containing film 130, may be formed on the lower structure 120.

The substrate 110 may include a semiconductor (e.g., silicon (Si) or germanium (Ge) or a compound semiconductor (e.g., silicon germanium (SiGe), silicon carbide (SiC), gallium arsenide (GaAs), indium arsenide (InAs), or indium phosphide (InP). The substrate 110 may include a conductive region. The conductive region may include a doped well, a doped structure, or a conductive layer.

The lower structure 120 may include an insulating film, which includes a silicon oxide film, a silicon nitride film, or a combination thereof. In an implementation, the lower structure 120 may include various conductive regions (e.g., wiring layers, contact plugs, and transistors) and insulating patterns configured to insulate the conductive regions from each other.

The metal-containing film 130 may include a metal film or an alloy film. In an implementation, the metal-containing film 130 may include, e.g., a Cu film, a Cu alloy film, a Mo film, a Mo alloy film, a W film, a W alloy film, a Co film, a Co alloy film, a ruthenium (Ru) film, a Ru alloy film, or a combination thereof. In an implementation, the metal-containing film 130 may include a Cu film.

Referring to FIGS. 2 and 3B, in process P14, the metal-containing film 130 may be polished by a CMP process using a metal-polishing slurry composition SC according to an embodiment. As a result, a metal-containing pattern 130P having a smaller thickness than the metal-containing film 130 may be obtained. For brevity, an upper portion of the metal-containing film 130 shown in FIG. 3A is illustrated with a dashed line in FIG. 3B. A detailed composition of the metal-polishing slurry composition SC may be the same as that described above.

The polishing process on the metal-containing film 130, which is shown in process P14 of FIG. 2 and FIG. 3B, may be a process of buff polishing the metal-containing film 130 by using the metal-polishing slurry composition SC to remove local steps or unevenness on a top surface of the metal-containing film 130 or remove seams in an upper portion of the metal-containing film 130. The metal-containing pattern 130P, which is obtained by buff polishing the metal-containing film 130, may have a smooth and flat top surface.

In an implementation, the metal-polishing slurry composition SC used in the polishing process on the metal-containing film 130, which is shown in process P14 of FIG. 2 and FIG. 3B, may include an abrasive-free slurry composition that does not include an inorganic abrasive.

In an implementation, a first organic polishing booster included in the metal-polishing slurry composition SC may include a polymer including a structural unit represented by one of Formulae 1 to 6 described above. In an implementation, in the metal-polishing slurry composition SC, the first organic polishing booster may include a polymer including a structural unit represented by one of Formulae 1 to 3 described above. In the polymer including a structural unit represented by Formula 1, X may be Cl. In the polymer including a structural unit represented by Formula 2, X may be Br, p may be 5, and q may be 3. In the polymer including a structural unit represented by Formula 3, X may be Cl. A detailed composition of the metal-polishing slurry composition SC may be the same as that described above.

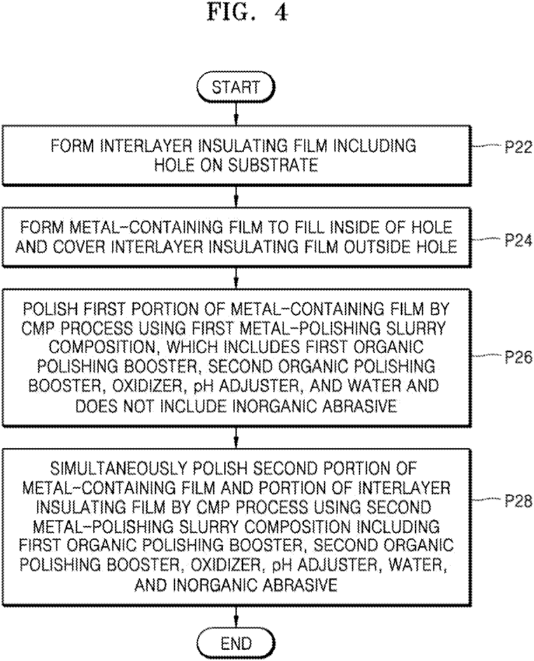

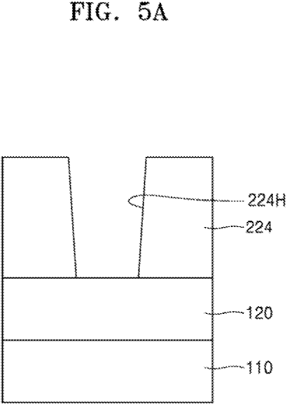

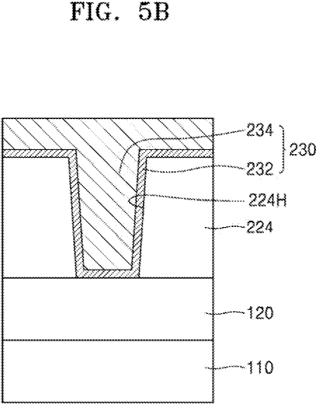

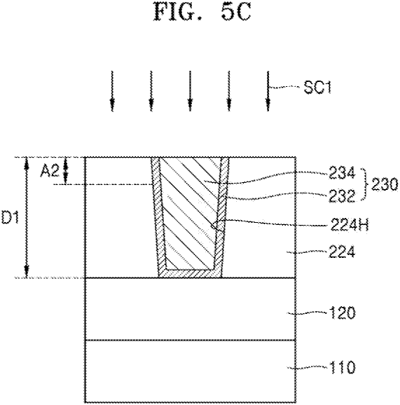

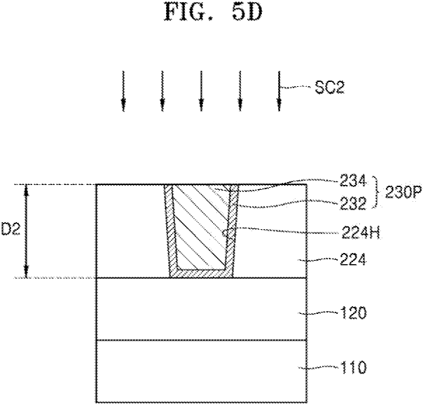

FIG. 4 is a flowchart of a method of manufacturing an IC device, according to embodiments. FIGS. 5A to 5D are cross-sectional views of stages in a method of manufacturing an IC device, according to embodiments.

Referring to FIGS. 4 and 5A, in process P22, a lower structure 120 may be formed on a substrate 110, and an interlayer insulating film 224 including a hole 224H may be formed on the lower structure 120.

The substrate 110 and the lower structure 120 may be the same as those described with reference to FIG. 3A. In an implementation, the lower structure 120 may be omitted.

In an implementation, to form the interlayer insulating film 224 including the hole 224H, initially, the interlayer insulating film 224 may be formed on the lower structure 120. Then the hole 224H passing through the interlayer insulating film 224 and exposing a conductive region of the lower structure 120 may be formed.

In an implementation, the interlayer insulating film 224 may include a silicon oxide film. In an implementation, the interlayer insulating film 224 may include, e.g., plasma enhanced oxide (PEOX), tetraethyl orthosilicate (TEOS), boro TEOS (BTEOS), phosphorous TEOS (PTEOS), boro phospho TEOS (BPTEOS), boro silicate glass (BSG), phospho silicate glass (PSG), boro phospho silicate glass (BPSG), or a combination thereof. In an implementation, the interlayer insulating film 224 may include an ultra-low K (ULK) film having a ultra-low dielectric constant K of about 2.2 to about 2.4. The ULK film may include, e.g., a silicon oxycarbonitride (SiOCN) film, a silicon oxycarbide (SiOC) film, a SiCOH film, or a combination thereof.

Referring to FIGS. 4 and 5B, in process P24, a metal-containing film 230 may be formed to fill the hole 224H of the interlayer insulating film 224 and cover the interlayer insulating film 224 outside the hole 224H. The metal-containing film 230 may be formed to be electrically connectable to a conductive region of the lower structure 120.

The metal-containing film 230 may include a conductive barrier film 232 and a metal film 234. The conductive barrier film 232 may conformally cover an inner wall of the hole 224H and a top surface of the interlayer insulating film 224. The metal film 234 may fill the hole 224H and cover the top surface of the interlayer insulating film 224 on the conductive barrier film 232. In an implementation, the conductive barrier film 232 may include Ti, TiN, Ta, TaN, or a combination thereof. The metal film 234 may include, e.g., copper (Cu), tungsten (W), aluminum (Al), cobalt (Co), or a combination thereof. In an implementation, the conductive barrier film 232 may include titanium nitride (TiN), and the metal film 234 may include Cu.

In an implementation, to form the conductive barrier film 232 and the metal film 234, a process including a physical vapor deposition (PVD) process, a chemical vapor deposition (CVD) process, an atomic layer deposition (ALD) process, an electroplating process, or a combination thereof may be employed.

In an implementation, the metal-containing film 230 may be connected to conductive regions (e.g., source/drain regions or a gate electrode of a transistor, a bit line, and a wiring layer) formed on the substrate 110.

Referring to FIGS. 4 and 5C, in process P26, in the resultant structure of FIG. 5B, a first portion A1 (refer to FIG. 5B) of the metal-containing film 230 may be polished by a CMP process using a first metal-polishing slurry composition SC1 until the top surface of the interlayer insulating film 224 is exposed. As a result, a top surface of the metal-containing film 230 may be substantially at the same level as the top surface of the interlayer insulating film 224.

During the polishing of the first portion A1 of the metal-containing film 230, the conductive barrier film 232 and the metal film 234, which are in the first portion A1 of the metal-containing film 230, may be removed together due to a CMP process using the first metal-polishing slurry composition SC1.

The first metal-polishing slurry composition SC1 may substantially have the same composition as the metal-polishing slurry composition SC described above. In an implementation, the first metal-polishing slurry composition SC1 may be an abrasive-free slurry composition that does not include an inorganic abrasive.

In an implementation, a first organic polishing booster included in the first metal-polishing slurry composition SC1 may include a polymer including a structural unit represented by one of Formulae 1 to 6 described above. In an implementation, in the first metal-polishing slurry composition SC1, the first organic polishing booster may include a polymer including a structural unit represented by one of Formulae 1 to 3 described above. In the polymer including a structural unit represented by Formula 1, X may be chlorine (Cl). In the polymer including a structural unit represented by Formula 2, X may be bromine (Br), p may be 5, and q may be 3. In the polymer including a structural unit represented by Formula 3, X may be Cl. A detailed composition of the first metal-polishing slurry composition SC1 may be the same as that of the metal-polishing slurry composition SC, which has been provided above.

As shown in FIG. 5C, after the first portion A1 (refer to FIG. 5B) of the metal-containing film 230 is removed by polishing, the interlayer insulating film 224 remaining around the metal-containing film 230 may have a first thickness D1. By polishing the metal-containing film 230 by using the first metal-polishing slurry composition SC1, the first portion A1 (refer to FIG. 5B) of the metal-containing film 230 may be removed at a relatively high polishing rate. In addition, the first metal-polishing slurry composition SC1 may not include the inorganic abrasive, and defects (e.g., scratches) or physical damage may not occur on a top surface of the resultant structure in which the first portion A1 (refer to FIG. 5B) of the metal-containing film 230 is removed by a polishing process using the first metal-polishing slurry composition SC1.

If the metal-containing film 230 were to have a damaged top surface in the resultant structure of FIG. 5C, a deteriorated profile of the damaged top surface could be transferred to a subsequent process. As a result, a wiring pattern (refer to 230P in FIG. 5D) to be finally obtained from the metal-containing film 230 may also have a top surface with a deteriorated profile. In this case, problems (e.g., an increase or nonuniformity in the resistance of the wiring pattern 230P) could occur, and the electrical properties of the IC device including the wiring pattern 230P could be degraded. In an implementation, the first portion (refer to A1 in FIG. 5B) of the metal-containing film 230 may be removed by a polishing process using the first metal-polishing slurry composition SC1 including no inorganic abrasive, and after the first portion A1 of the metal-containing film 230 is removed, there may be little to no occurrence of defects (e.g., scratches) or physical damage on the top surface of the metal-containing film 230.

Referring to FIGS. 4 and 5D, in process P28, in the resultant structure of FIG. 5C, a second portion A2 (refer to FIG. 5C) of the metal-containing film 230 and a portion of the interlayer insulating film 224 may be simultaneously polished by a CMP process using a second metal-polishing slurry composition SC2, and thus, the wiring pattern 230P may be formed to fill the hole 224H.

During the polishing of the second portion A2 of the metal-containing film 230 and the portion of the interlayer insulating film 224, the conductive barrier film 232 and the metal film 234, which are in the second portion A2 of the metal-containing film 230, may be removed together by the CMP process using the second metal-polishing slurry composition SC2.

The second metal-polishing slurry composition SC2 may include the same components as those included in the first metal-polishing slurry composition SC1 except that the second metal-polishing slurry composition SC2 may further include an inorganic abrasive. In an implementation, in the second metal-polishing slurry composition SC2, the inorganic abrasive may be included in an amount of, e..g, about 0.1 wt% to about 20.0 wt%, based on the total weight of the second metal-polishing slurry composition SC2.

In addition to the described methods of manufacturing an IC device, it will be understood that IC devices having various wiring structures may be manufactured by making various modifications and changes. In a method of manufacturing the IC device according to an embodiment, a metal wiring pattern may be formed by polishing a metal-containing film by using a metal-polishing slurry composition described above, and thus, an IC device having improved reliability may be provided.

One or more embodiments may provide a metal-polishing slurry composition, which may increase a polishing rate of a metal-containing film while preventing defects (e.g., scratches) on a polished surface of the metal-containing film or physical damage to the polished surface of the metal-containing film during the polishing of the metal-containing film, and may improve an etch selectivity of the metal-containing film with respect to an insulating film adjacent thereto.

One or more embodiments may provide a method of manufacturing an integrated circuit (IC) device, which may improve the reliability of metal wiring patterns by increasing a polishing rate of a metal-containing film while preventing defects (e.g., scratches) on a polished surface of the metal-containing film or physical damage to the polished surface of the metal-containing film during the polishing of the metal-containing film, and improving an etch selectivity of the metal-containing film with respect to an insulating film adjacent thereto.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A slurry composition for polishing metal, the slurry composition comprising:
a first organic polishing booster including a cationic polymer salt that includes a quaternary ammonium cation;
a second organic polishing booster including an organic acid;
an oxidizer;
a pH adjuster;
0 wt% to about 0.1 wt% of an inorganic abrasive; and
water.

2. The slurry composition as claimed in claim 1, wherein the slurry composition includes 0 wt% of the inorganic abrasive.

3. The slurry composition as claimed in claim 1, wherein the slurry composition is formulated for polishing a copper (Cu)-containing film.

4. The slurry composition as claimed in claim 1, wherein:
the first organic polishing booster includes a polymer including a structural unit represented by one of Formulae 1 to 6: 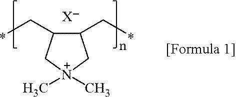 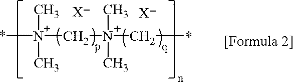
in Formula 1, X is fluorine (F), chlorine (Cl), bromine (Br), or iodine (I), and n is an integer such that a weight average molecular weight of the polymer including the structural unit represented by Formula 1 is about 1,000 to about 1,000,000,
in Formula 2, each X is independently F, Cl, Br, or I, p and q are each independently an integer of 1 to 5, and n is an integer such that a weight average molecular weight of the polymer including the structural unit represented by Formula 2 is about 1,000 to about 1,000,000, 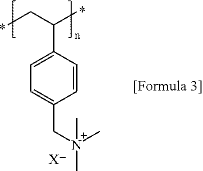 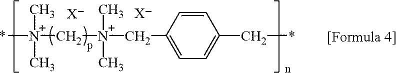
in Formula 3, X is F, Cl, Br, or I, and n is an integer such that a weight average molecular weight of the polymer including the structural unit represented by Formula 3 is about 1,000 to about 1,000,000,
in Formula 4, each X is independently F, Cl, Br, or I, p is an integer of 1 to 5, and n is an integer such that a weight average molecular weight of the polymer including the structural unit represented by Formula 4 is about 1,000 to about 1,000,000, 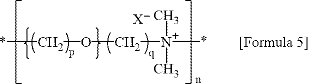 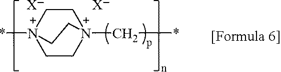
in Formula 5, X is F, Cl, Br, or I, p and q are each independently an integer of 1 to 5, and n is an integer such that a weight average molecular weight of the polymer including the structural unit represented by Formula 5 is about 1,000 to about 1,000,000,
in Formula 6, each X is independently F, Cl, Br, or I, p is an integer of 1 to 5, and n is an integer such that a weight average molecular weight of the polymer including the structural unit represented by Formula 6 is about 1,000 to about 1,000,000.

5. The slurry composition as claimed in claim 1, wherein the slurry composition includes about 0.001 wt% to about 10 wt% of the first organic polishing booster.

6. The slurry composition as claimed in claim 1, wherein the second organic polishing booster includes arginine, histidine, lysine, aspartic acid, glutamic acid, serine, threonine, asparagine, glutamine, cysteine, selenocysteine, glycine, proline, alanine, valine, leucine, isoleucine, methionine, phenylalanine, tyrosine, tryptophan, carboxylic acid, or a combination thereof.

7. The slurry composition as claimed in claim 1, wherein the slurry composition includes about 0.001 wt% to about 10 wt% of the second organic polishing booster.

8. The slurry composition as claimed in claim 1, wherein, in the slurry composition, an amount of the first organic polishing booster is lower than an amount of the second organic polishing booster.

9. The slurry composition as claimed in claim 1, wherein the oxidizer includes a peroxide, a permanganate, a periodate, an iodate, a nitrate, hypochlorous acid, a hypochlorite, a persulfate, or a combination thereof.

10. The slurry composition as claimed in claim 1, further comprising a corrosion inhibitor, the corrosion inhibitor including a water-soluble polymer containing an azole-containing compound or an anionic carboxylic acid.

11. The slurry composition as claimed in claim 1, further comprising a catalyst, the catalyst including an iron-containing compound.

12. The slurry composition as claimed in claim 1, wherein:
the slurry composition includes more than 0 wt% and equal to or less than 0.1 wt% of the inorganic abrasive, and
the inorganic abrasive includes silica, alumina, ceria, titania, zirconia, magnesia, germania, mangania, or a combination thereof.

13. A slurry composition for processing a surface of a metal-containing film-containing object to be polished by a chemical mechanical polishing (CMP) process, the slurry composition comprising:
a first organic polishing booster including a cationic polymer salt that includes a quaternary ammonium cation;
a second organic polishing booster including an organic acid;
an oxidizer;
a pH adjuster; and
water.

14. The slurry composition as claimed in claim 13, wherein:
the first organic polishing booster includes a polymer including a structural unit represented by one of Formulae 1 to 3: 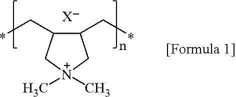 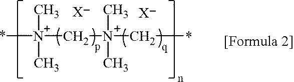
in Formula 1, X is chlorine (Cl), and n is an integer such that a weight average molecular weight of the polymer including the structural unit represented by Formula 1 is about 1,000 to about 1,000,000,
in Formula 2, X is bromine (Br), p is 5, q is 3, and n is an integer such that a weight average molecular weight of the polymer including the structural unit represented by Formula 2 is about 1,000 to about 1,000,000, 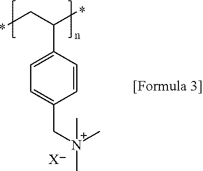
in Formula 3, X is Cl, and n is an integer such that a weight average molecular weight of the polymer including the structural unit represented by Formula 3 is about 1,000 to about 1,000,000.

15. The slurry composition as claimed in claim 13, wherein:
the object to be polished includes a copper (Cu) film, and
the slurry composition is free of an inorganic abrasive.

16. The slurry composition as claimed in claim 13, wherein:
the object to be polished includes a copper (Cu) film and a silicon oxide film, and
the slurry composition further includes an inorganic abrasive.

17. The slurry composition as claimed in claim 13, further comprising a corrosion inhibitor or a catalyst, wherein:
the corrosion inhibitor includes a water-soluble polymer includes an azole-containing compound or an anionic carboxylic acid, and
the catalyst includes an iron-containing compound.

18. A slurry composition for polishing metal, the slurry composition being formulated to process a surface of an object to be polished by a chemical mechanical polishing (CMP) process such that the object includes a copper (Cu) film, the slurry composition comprising:
a first organic polishing booster including a cationic polymer salt including a quaternary ammonium cation;
a second organic polishing booster including an organic acid;
an oxidizer;
a pH adjuster; and
water,
wherein the slurry composition is free of an inorganic abrasive.

19. The slurry composition as claimed in claim 18, wherein:
the slurry composition includes:
about 0.001 wt% to about 10 wt% of the first organic polishing booster, and
about 0.001 wt% to about 10 wt% of the second organic polishing booster, an amount of the first organic polishing booster being lower than an amount of the second organic polishing booster, and
the first organic polishing booster includes a polymer having a structural unit represented by one of Formulae 1 to 3, 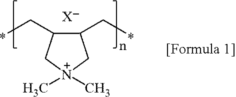 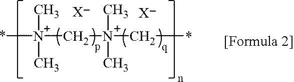
in Formula 1, X is chlorine (Cl), and n is an integer such that a weight average molecular weight of the polymer including the structural unit represented by Formula 1 is about 1,000 to about 1,000,000,
in Formula 2, each X is bromine (Br), p is 5, q is 3, and n is an integer such that a weight average molecular weight of the polymer including the structural unit represented by Formula 2 is about 1,000 to about 1,000,000, 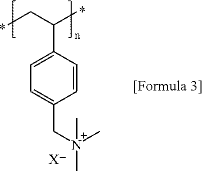
in Formula 3, X is Cl, and n is an integer such that a weight average molecular weight of the polymer including the structural unit represented by Formula 3 is about 1,000 to about 1,000,000.

20. The slurry composition as claimed in claim 18, further comprising a corrosion inhibitor or a catalyst, wherein:
the corrosion inhibitor includes a water-soluble polymer that includes an azole-containing compound or an anionic carboxylic acid, and
the catalyst includes an iron-containing compound.

21-40. (canceled)
